(19) United States
(12) Patent Application Publication
(10) Pub. No.: US 2007/0128551 A1
(43) Pub. Date: Jun. 7, 2007

(54) Manufacturing method of thin film transistor array panel

(75) Inventor: Eun-Guk Lee, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/522,048

(22) Filed: Sep. 15, 2006

(30) Foreign Application Priority Data
Nov. 18, 2005 (KR) 10-2005-0110536

(51) Int. Cl. G03F 7/00; H01L 29/04; H01L 29/15; H01L 31/036

(52) U.S. Cl. 430/311; 257/72

(57) ABSTRACT

A method of manufacturing a thin film transistor array panel. The method includes forming an amorphous silicon layer, an insulating layer, and a conductive layer on a substrate, forming a first photoresist having a first portion and a second portion with a thickness less than the first portion on the conductive layer, and simultaneously etching the conductive layer, the insulating layer, and the amorphous silicon layer using the first photoresist as a mask. The method also includes removing the second portion of the first photoresist, removing an exposed portion of the conductive layer using the first portion of the first photoresist as a mask to form a gate line and a metal pattern for a data line. The remaining portion of the first photoresist is removed and an impurity is doped to form a semiconductor having a source area and a drain area. The method also includes forming a passivation layer on the gate line, the metal pattern for a data line, the exposed insulating layer, and the exposed substrate, forming a second photoresist having a first portion and a second portion with a thickness less than the first portion on the passivation layer, etching the passivation layer using the second photoresist as a mask to expose a portion of the metal pattern for a data line and a portion of a area enclosed by the gate line and the metal pattern, removing the second portion of the second photoresist, depositing a conductive film, and removing the second photoresist to form a data line and a pixel electrode.

### CROSS-REFERENCE TO RELATED APPLICATION

This application claims priority to Korean Patent Application No. 10-2005-0110536 filed on Nov. 18, 2005, the contents of which are incorporated herein by reference in their entirety.

### BACKGROUND OF THE INVENTION

(a) Technical Field

The present invention relates to a thin film transistor array panel and a manufacturing method thereof.

(b) Discussion of the Related Art

Active matrix display devices such as a liquid crystal display (LCD) and an organic light emitting display (OLED) include a plurality of pixels arranged in a matrix. The pixels include a switching element such as a thin film transistor (TFT) having a gate electrode, a source electrode, and a drain electrode. The TFT transmits a data signal, which is applied to the source electrode, to a pixel electrode in response to a gate signal applied to the gate electrode.

The display devices include a thin film transistor array panel, which includes the TFTs, pixel electrodes, and a plurality of signal lines such as gate lines and data lines to transmit signals to the TFTs. The TFT array panel has a multiple layered structure, including thin conductive films and insulating layers.

Conventionally, photolithography and etching steps are used repeatedly to pattern multiple thin film layers to form the TFT array panel. The photolithography steps increase manufacturing cost and time. Therefore, there is a need for reducing the number of photolithography steps.

### SUMMARY OF THE INVENTION

In accordance with an embodiment of the present invention, a method of manufacturing a thin film transistor (TFT) array panel includes forming an amorphous silicon layer, an insulating layer, and a conductive layer on a substrate, forming a first photoresist having a first portion and a second portion with a thickness less than the first portion on the conductive layer, and simultaneously etching the conductive layer, the insulating layer, and the amorphous silicon layer using the first photoresist as a mask. The second portion of the first photoresist, and an exposed portion of the conductive layer are removed using the first portion of the first photoresist as a mask to form a gate line and a metal pattern for a data line. The remaining first photoresist is removed and an impurity is doped to form a semiconductor having a source area and a drain area. A passivation layer is formed on the gate line, the metal pattern for a data line, an exposed portion of the insulating layer, and an exposed portion of the substrate. The method further includes forming a second photoresist having a first portion and a second portion with a thickness less than the first portion on the passivation layer, etching the passivation layer using the second photoresist as a mask to expose a portion of the metal pattern for a data line and a portion of an area enclosed by the gate line and the metal pattern, removing the second portion of the second photoresist, depositing a conductive film, and removing the second photoresist to form a data line and a pixel electrode.

The conductive film may include a first portion disposed on the second photoresist and a second portion, and when the second photoresist is removed, the first portion of the conductive film is substantially simultaneously removed.

The first photoresist and the second photoresist may be formed using a photomask having a light blocking area, a translucent area, and a light transmitting area.

The first portions of the first photoresist and the second photoresist may have reduced thicknesses after the second portions of the first photoresist and the second photoresist are removed.

The removal of the second portions of the first photoresist and the second photoresist may include an ashing process.

The etching of the passivation layer may include exposing a portion of the gate line, and the formation of the data line and the pixel electrode comprises forming a contact assistant on an exposed portion of the gate line.

A thin film transistor array panel, according to an embodiment of the present invention, includes a semiconductor formed on a substrate and having a source area and a drain area, an insulating layer formed on the semiconductor, a gate line and a metal pattern for a data line formed on the insulating layer, and a passivation layer formed on the gate line and the metal pattern for a data line. The passivation layer includes a first opening exposing the metal pattern for a data line and a second opening exposing an area enclosed by the gate line and the metal pattern for a data line. A data line is formed on an exposed portion of the metal pattern for a data line and is connected to the source area. A pixel electrode is formed on an exposed portion of the area enclosed by the gate line and the metal pattern for a data line and is connected to the drain area.

The passivation layer may be formed on an overlapping area of the pixel electrode and the gate line.

The passivation layer may further include a contact hole exposing a portion of the gate line.

The thin film transistor array panel may further include a contact assistant formed on an exposed portion of the gate line.

The contact assistant may have a boundary that is substantially the same as a boundary of the contact hole.

The data line may have a boundary that is substantially the same as the boundary of the first opening.

The pixel electrode may have a boundary that is substantially the same as the boundary of the second opening.

The thin film transistor array panel may further include a storage electrode overlapping a portion of the pixel electrode.

The storage electrode may be connected to a gate line.

The semiconductor may have substantially the same planar shape as the insulating layer, the metal pattern for a data line, and the gate line except for the source area and the drain area.

A thin film transistor array panel, according to an embodiment of the present invention, includes a semiconductor formed on a substrate and having a source area and a drain area, an insulating layer formed on the semiconductor, a gate line and a metal pattern for a data line formed on the insulating layer, a passivation layer formed on the gate line and the metal pattern for a data line, and a pixel electrode connected to the drain area.

The passivation layer may have a first opening exposing the metal pattern for a data line and a second opening exposing an area enclosed by the gate line.

### BRIEF DESCRIPTION OF THE DRAWINGS

Exemplary embodiments of the present invention can be understood in more detail with reference to the accompanying drawings, in which:

FIG. 1 is a layout view of a TFT array panel according to an exemplary embodiment of the present invention.

FIGS. 2A and 2B are sectional views of the TFT array panel shown in FIG. 1 taken along the lines IIA-IIA and IIB-IIB, respectively.

FIGS. 3A and 3B are sectional views of the TFT array panel shown in FIG. 1 taken along the lines IIA-IIA and IIB-IIB, respectively, in a step of a manufacturing method of the TFT array panel according to an exemplary embodiment of the present invention.

FIGS. 4A and 4B illustrate a step following the step shown in FIGS. 3A and 3B.

FIGS. 5A and 5B illustrate a step following the step shown in FIGS. 4A and 4B.

FIGS. 6A and 6B illustrate a step following the step shown in FIGS. 5A and 5B.

FIGS. 7A and 7B illustrate a step following the step shown in FIGS. 6A and 6B.

FIG. 8 is a layout view of the TFT array panel shown in FIGS. 1-2B at an intermediate step of a manufacturing method thereof according to an exemplary embodiment of the present invention.

FIGS. 9A and 9B are sectional views of the TFT array panel shown in FIG. 8 taken along the lines IXA-IXA and IXB-IXB, respectively.

FIGS. 10A and 10B illustrate a step following the step shown in FIGS. 9A and 9B.

FIGS. 11A and 11B illustrate a step following the step shown in FIGS. 10A and 10B.

FIGS. 12A and 12B illustrate a step following the step shown in FIGS. 11A and 11B.

FIGS. 13A and 13B illustrate a step following the step shown in FIGS. 12A and 12B.

FIGS. 14A and 14B illustrate a step following the step shown in FIGS. 13A and 13B.

### DETAILED DESCRIPTION OF THE EMBODIMENTS

Exemplary embodiments of the present invention will be described more fully hereinafter with reference to the accompanying drawings. This invention may, however, be embodied in many different forms and should not be construed as limited to the embodiments set forth herein. Like numerals refer to like elements throughout.

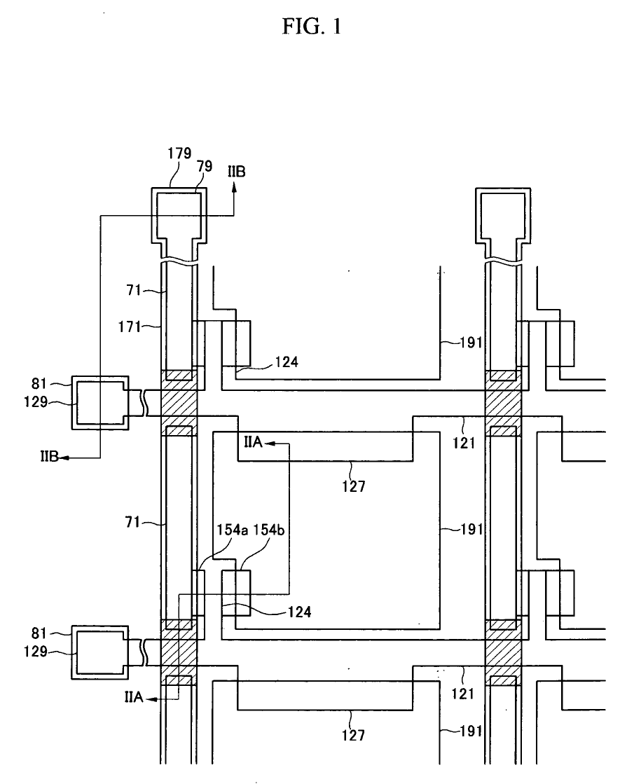

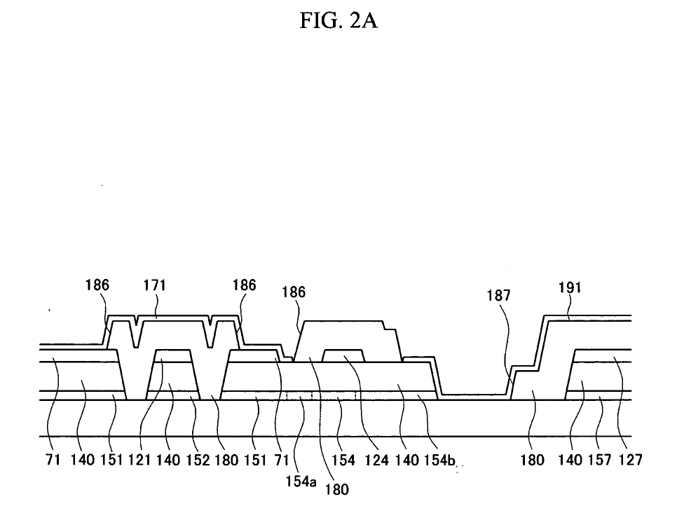

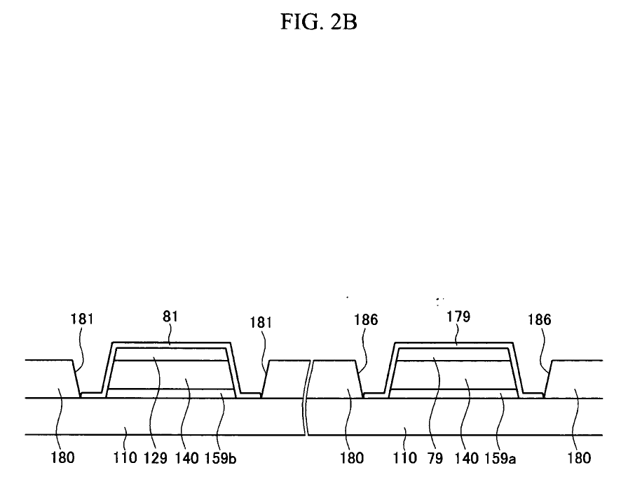

In the drawings, the thickness of layers and regions are exaggerated for clarity. It will be understood that when an element such as a layer, region, or substrate is referred to as being “on” another element, it can be directly on the other element or intervening elements may also be present. A TFT array panel according to an embodiment of the present invention will be described with reference to FIGS. 1, 2A, and 2B.

FIG. 1 is a layout view of a TFT array panel according to an embodiment of the present invention. FIG. 2A is a sectional view of the TFT array panel shown in FIG. 1 taken along the line IIA-IIA, and FIG. 2B is a sectional view of the TFT array panel shown in FIG. 1 taken along the line IIB-IIB.

Referring to FIGS. 1 to 2B, a plurality of semiconductors 151 and 152 preferably made of, for example, hydrogenated amorphous silicon (“a-Si”) or polysilicon are formed on an insulating substrate 110 made of a material such as, for example, transparent glass or plastic.

More specifically, the semiconductors include a plurality of longitudinal portions 151 extending substantially in a longitudinal direction, and a plurality of transverse portions 152 extending between two adjacent longitudinal portions 151 substantially in a transverse direction.

Each of the longitudinal portions 151 includes a projection 154 projecting in a rightward direction with respect to the layout view in FIG. 1. Each of the semiconductors 151 formed at the uppermost portion and the lowermost portion, with respect to the layout view in FIG. 1, includes an end portion 159a having a large area. The projection 154 includes a source area 154a and a drain area 154b doped with an impurity. The source and drain areas 154a and 154b are made of, for example, n+ hydrogenated a-Si heavily doped with an n-type impurity such as, for example, phosphorous. Alternatively, the source and drain areas 154a and 154b may be made of silicide.

Each of the transverse portions 152 includes a plurality of expansions 157 projecting downward with respect to the layout view of FIG. 1 and an end portion 159b having a large area. The projection 154 of the longitudinal portion 151 and the expansion 157 of the transverse portion 152 adjacent to the projection 154 are connected to each other through a connection that is formed between the projection 154 and the transverse portion 152.

The lateral sides of the semiconductors 151 and 152 are inclined relative to a surface of the substrate 110, and the inclination angle thereof ranges from about 30 to about 80 degrees.

A gate insulating layer 140 made of, for example, silicon nitride (SiNx) or silicon oxide (SiOx) is formed on the semiconductors 151 and 152. The gate insulating layer 140 has substantially the same planar shape as the underlying semiconductors 151 and 152.

A plurality of metal patterns 71 for data lines and a plurality of gate lines 121 are formed on the gate insulating layer 140.

Each of the metal patterns 71 for a data line extends substantially in the longitudinal direction and has an island shape. As shown in FIG. 1, the end metal patterns 71 for data lines include an end portion 79 having a large area for contact with another layer or an external driving circuit formed at uppermost and lowermost portions thereof. Thereby, the metal patterns 71 for the data lines receive data signals through the end portions 79.

The gate lines 121 transmit gate signals and extend between the two adjacent metal patterns 71 for data lines substantially in the transverse direction. Referring to FIGS. 1 and 2A-2B, each of the gate lines 121 includes a plurality of gate electrodes 124 projecting upward, a plurality of expansions 127 projecting downward, and an end portion 129 having a large area for contact with another layer or an external driving circuit. A gate driving circuit (not shown) for generating the gate signals may be mounted on a flexible printed circuit (FPC) film (not shown), which may be attached to the substrate 110, directly mounted on the substrate 110, or integrated into the substrate 110. The gate lines 121 may extend to be connected to a driving circuit that may be integrated into the substrate 110.

The semiconductors 151 and 152 have substantially the same planar shape as the gate lines 121 or the metal patterns 71 for the data lines at most portions thereof. However, the semiconductors 151 and 152 include some exposed portions, which are not covered with the gate lines 121 or the metal patterns 71 for the data lines, such as the source areas 154a and the drain areas 154b.

A gate electrode 124, a source area 154a, and a drain area 154b along with a projection 154 of a semiconductor 151 form a TFT having a channel formed in the projection 154 of the semiconductor 151 disposed under a gate electrode 124.

The gate lines 121 and the metal patterns 71 for the data lines can be made from, for example, a refractory metal such as Cr, Mo, Ta, Ti, and/or alloys thereof. However, the gate lines and metal patterns for the data lines may have a multilayered structure including a refractory metal film (not shown) and a low resistivity film (not shown). Examples of the multi-layered structure are a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, the gate lines 121 and the metal patterns 71 for the data lines may be made of various metals or conductors.

The lateral sides of the gate lines 121 and the metal patterns 71 for the data lines are inclined relative to a surface of the substrate 110, and the inclination angle thereof ranges from about 30 to about 80 degrees.

A passivation layer 180 is formed on the metal patterns 71 for the data lines, the gate lines 121, and the exposed portions of the semiconductors 154a and 154b. The passivation layer 180 may be made of an inorganic or organic insulator, and it may have a flat top surface. Examples of the inorganic insulator include silicon nitride and silicon oxide. The organic insulator may, for example, have photosensitivity and a dielectric constant of less than about 4.0. The passivation layer 180 may include a lower film of an inorganic insulator and an upper film of an organic insulator, such that it takes the desired insulating characteristics of the organic insulator while preventing the exposed portions of the semiconductor 154a and 154b from being damaged by the organic insulator.

The passivation layer 180 has a plurality of contact holes 181 exposing the end portions 129 of the gate lines 121. The passivation layer 180 has a plurality of openings 186 exposing the metal patterns 71 for the data lines except for end-portions 79 of the metal patterns 71 for the data lines adjacent a gate line 121 formed between the two adjacent metal patterns 71, and a plurality of openings 187 exposing areas approximately enclosed by the metal patterns 71 for the data lines and the gate lines 121.

A plurality of data lines 171, a plurality of pixel electrodes 191, and a plurality of contact assistants 81 are formed in the openings 186, on the exposed portions of the passivation layer 180, and in the openings 187 and the contact holes 181. The data lines 171, pixel electrodes 191 and contact assistants 81 are made of, for example, a transparent conductor such as ITO or IZO or a reflective conductor such as Ag, Al, Cr, and/or alloys thereof.

The data lines 171 overlap the underlying metal patterns 71 for the data lines, to transmit data signals through the metal patterns 71 for the data lines, and extend substantially in the longitudinal direction to intersect the gate lines 121. Each of the data lines 171 includes an end portion. The data signals are physically and electrically connected to the data lines 171 since the metal patterns 71 for the data lines overlap the data lines 171, and are thereby transmitted to the source areas 154a of the expansions 154 of the semiconductors 151.

The pixel electrodes 191 are physically and electrically connected to the drain areas 154b of the expansions 154 such that the pixel electrodes 191 receive data voltages from the drain areas 154b. The pixel electrodes 191 supplied with the data voltages generate electric fields in cooperation with a common electrode (not shown) of an opposing display panel (not shown) supplied with a common voltage. The electric fields determine the orientations of liquid crystal molecules (not shown) of a liquid crystal layer (not shown) disposed between the two electrodes. Thereby, the polarization of light passing through the liquid crystal layer is varied by the orientations of the liquid crystal molecules. A pixel electrode 191 and a common electrode form a capacitor referred to as a “liquid crystal capacitor,” which stores applied voltages after the TFT turns off. An additional capacitor, which is connected in parallel to the liquid crystal capacitor, may be provided for enhancing the voltage storing capacity.

A storage capacitor is formed by overlapping of a pixel electrode 191 and a gate line 121 neighboring thereto (referred to as “a previous gate line”). For increasing capacitance of the storage capacitor, that is, storage ability, projections 127 are provided by expanding the gate line 121 to enlarge the overlapping areas between the pixel electrode 191 and the gate line 121.

The contact assistants 81 are connected to the end portions 129 of the gate lines 121. The contact assistants 81 protect the end portions 129 and enhance the adhesion between the end portions 129 and external devices. Like the contact assistants 81, the end portions 179 of the data lines 171 protect the end portions 79 of the metal patterns 71 for the data lines and enhance the adhesion between the end portions 79 and external devices.

The boundaries of the data lines 171, the pixel electrodes 191, and the contact assistants 81 are substantially the same as the boundaries of the openings 186 and 187 and the contact holes 181, respectively.

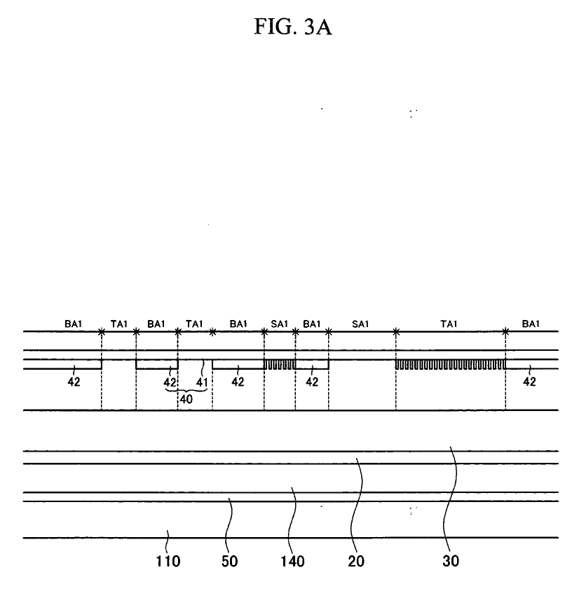

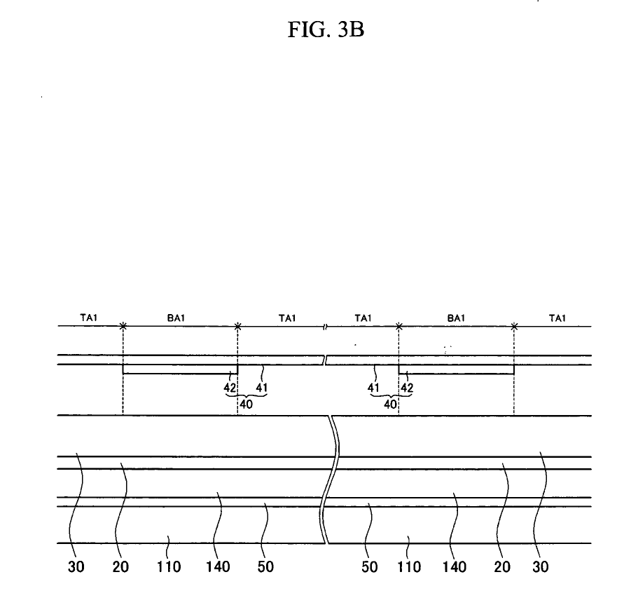

A method of manufacturing the TFT array panel shown in FIGS. 1-2B will be described in detail with reference to FIGS. 3A-14B as well as FIGS. 1-2B.

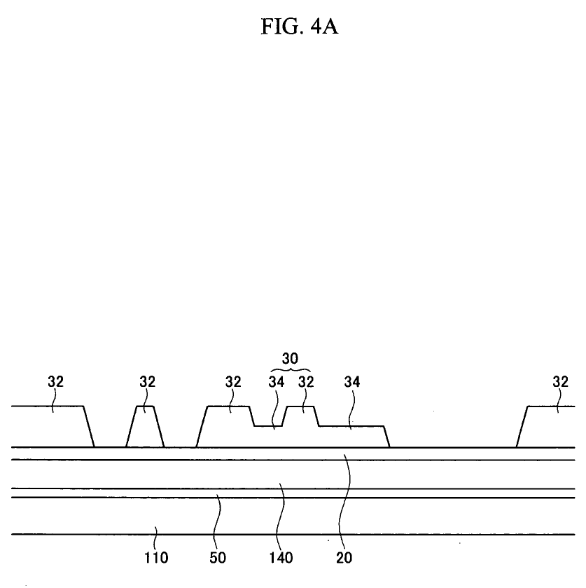

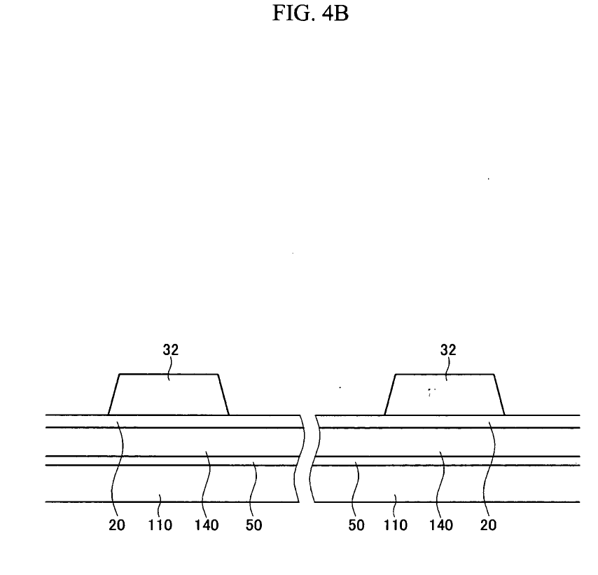

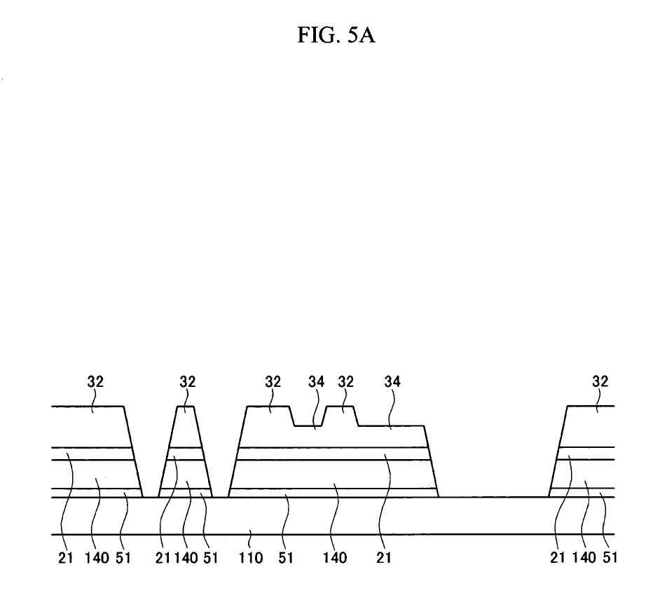

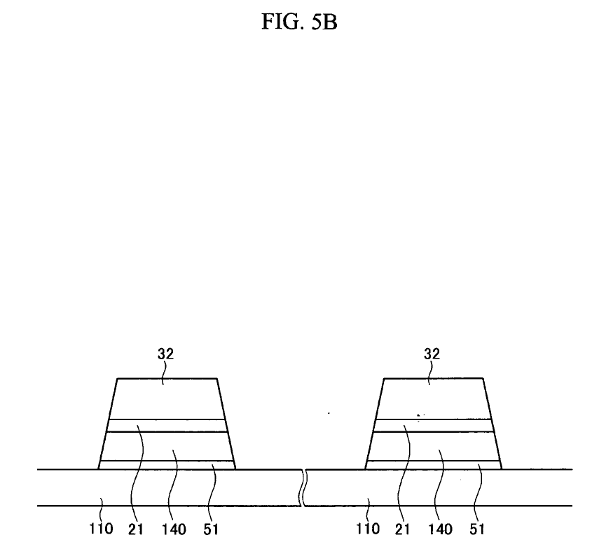

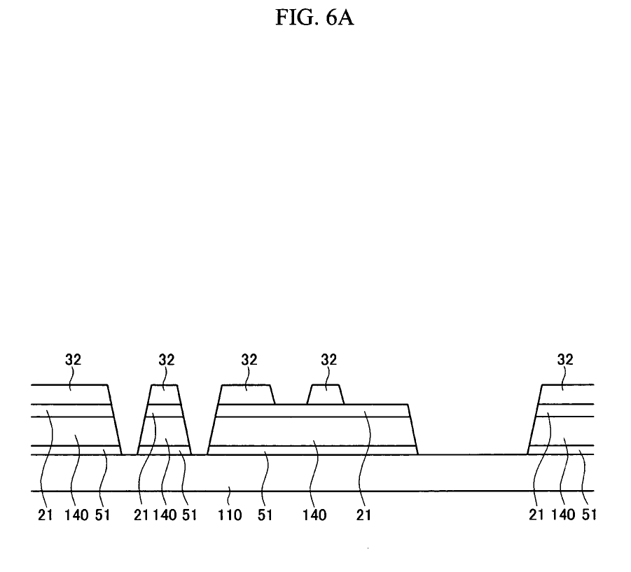

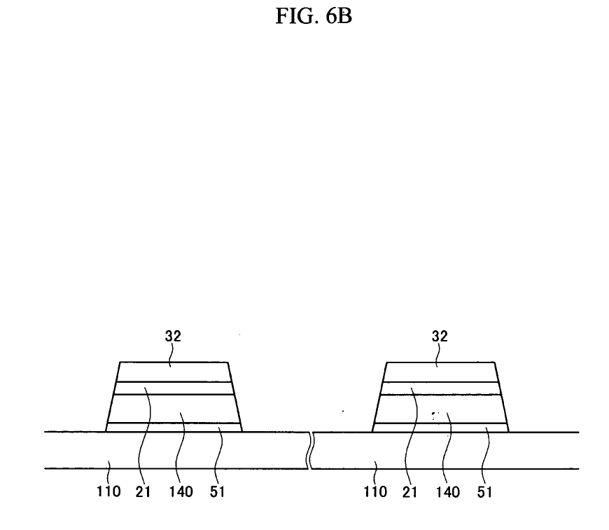

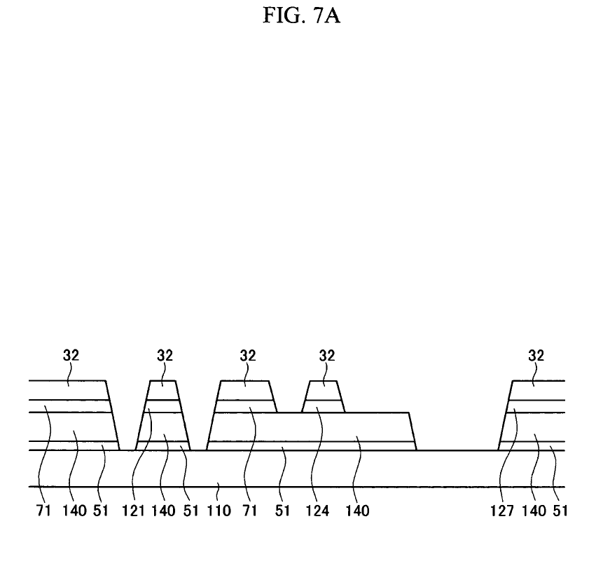

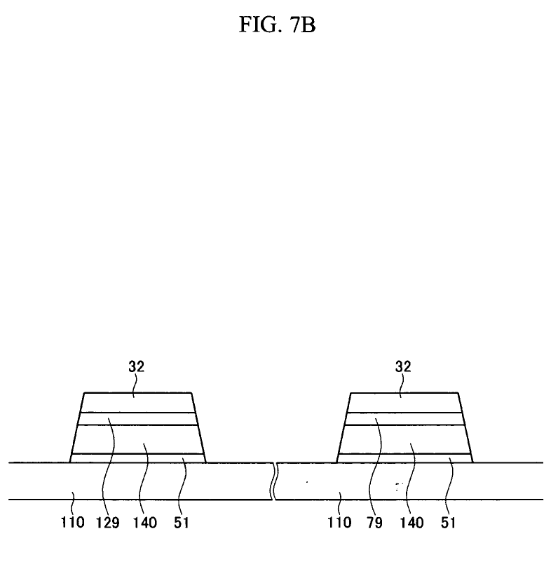

FIGS. 3A and 3B are sectional views of the TFT array panel shown in FIG. 1 taken along the lines IIA-IIA and IIB-IIB, in a step of a manufacturing method of the TFT array panel according to an exemplary embodiment of the present invention, respectively. FIGS. 4A and 4B illustrate a step following the step shown in FIGS. 3A and 3B. FIGS. 5A and 5B illustrate a step following the step shown in FIGS. 4A and 4B. FIGS. 6A and 6B illustrate a step following a step shown in FIGS. 5A and 5B. FIGS. 7A and 7B illustrate a step following the step shown in FIGS. 6A and 6B.

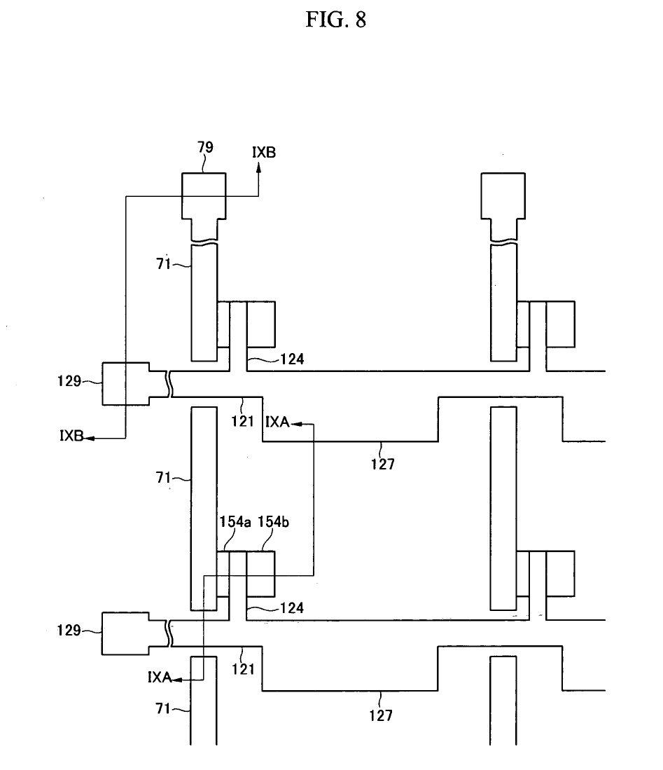

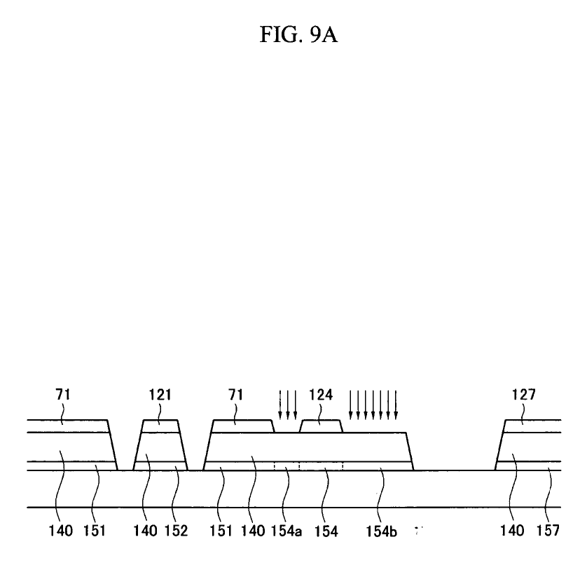

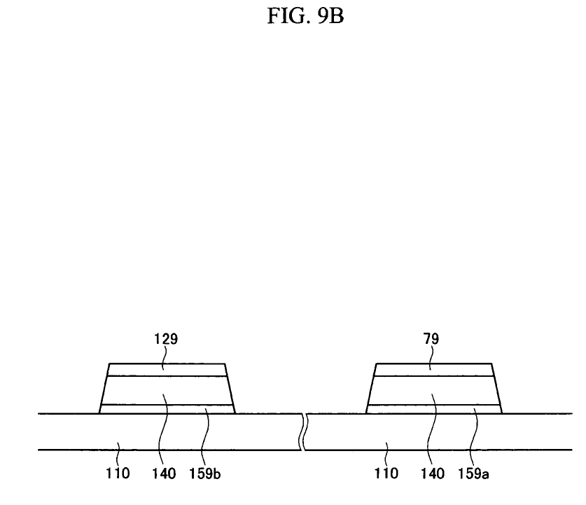

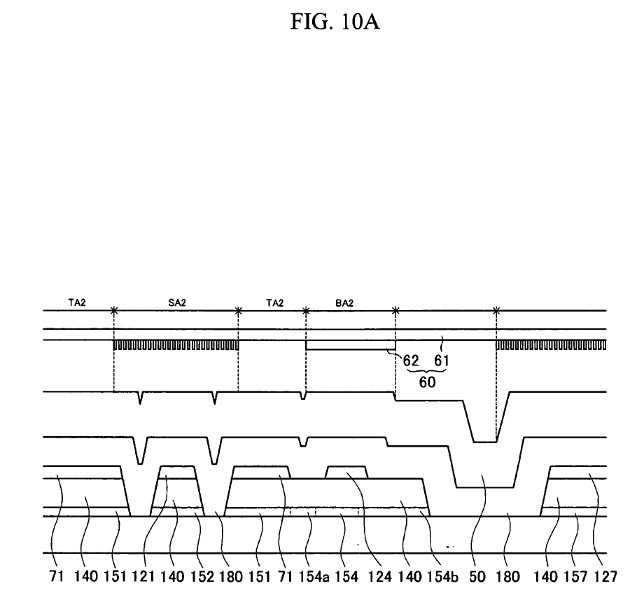

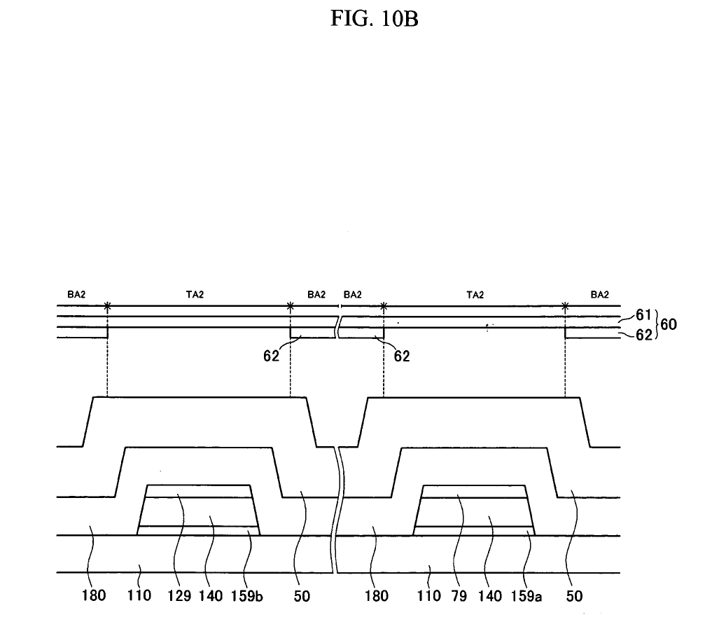

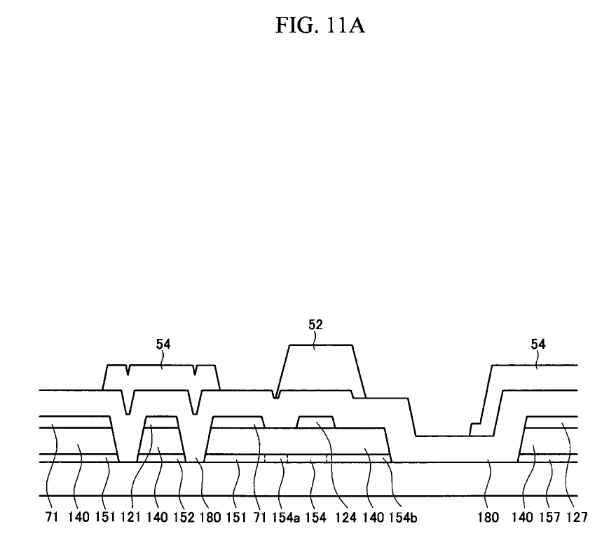

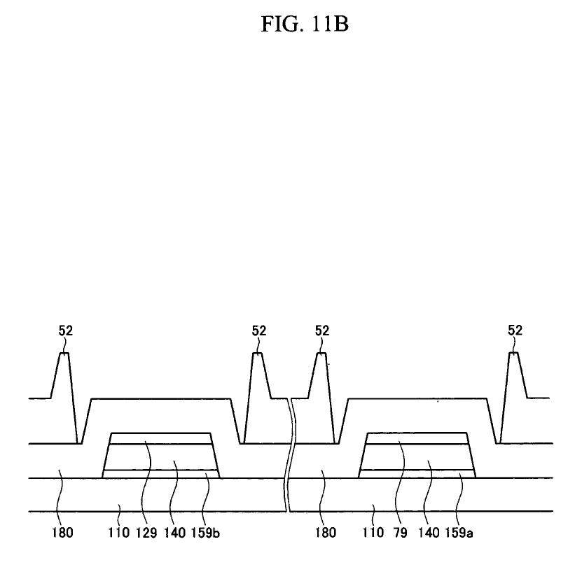

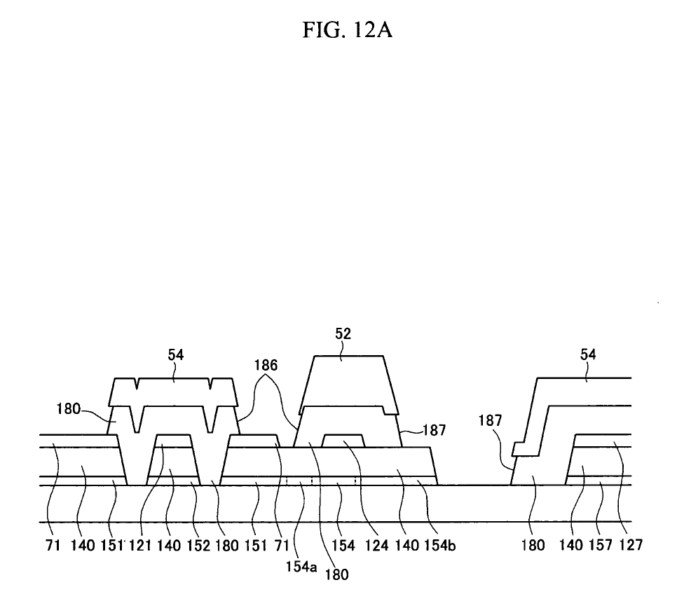

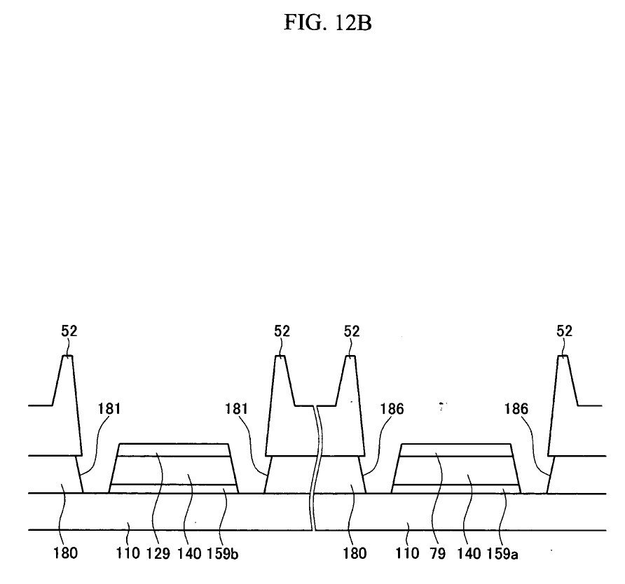

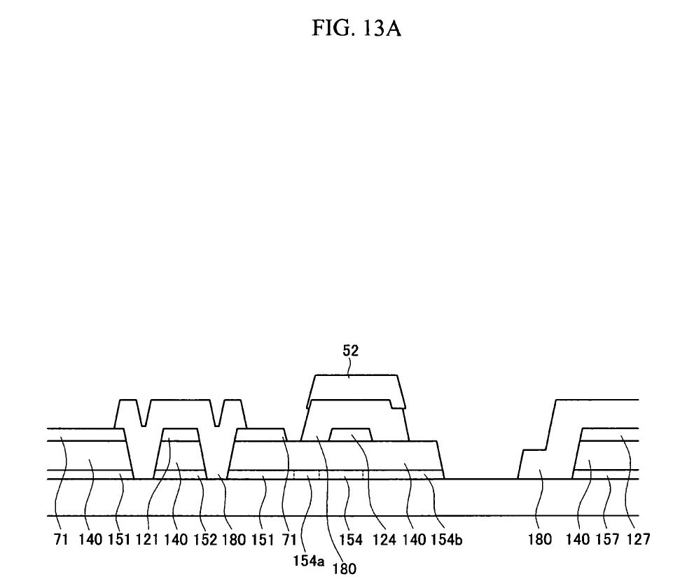

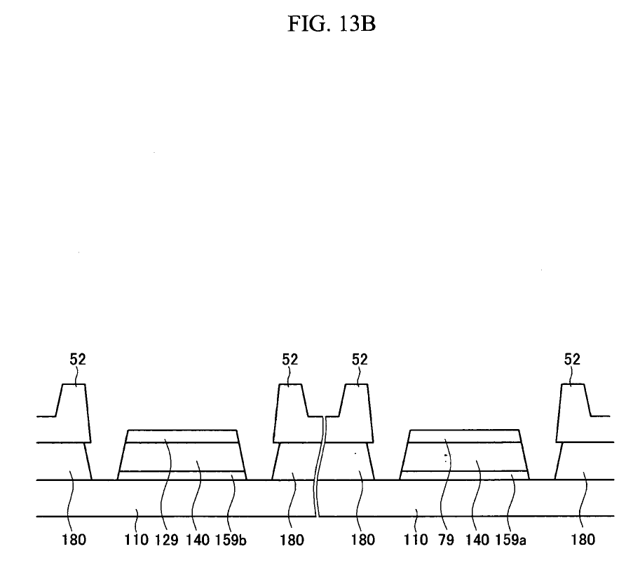

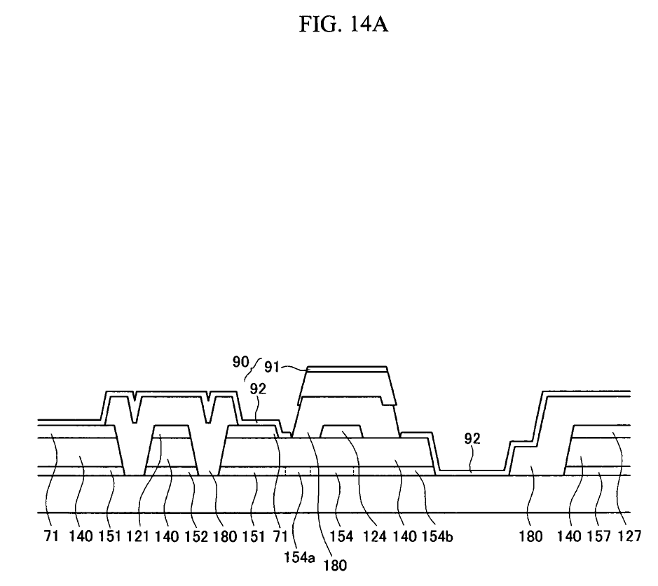

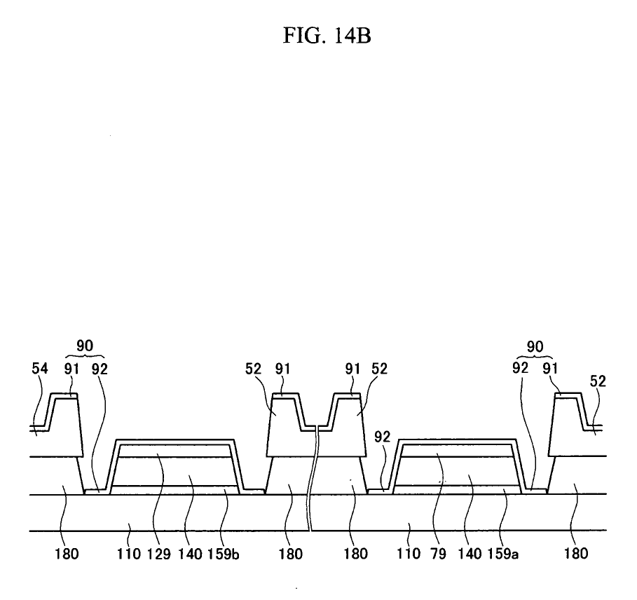

FIG. 8 is a layout view of the TFT array panel shown in FIGS. 1-2B at an intermediate step of a manufacturing method thereof according to an exemplary embodiment of the present invention. FIGS. 9A and 9B are sectional views of the TFT array panel shown in FIG. 8 taken along the lines IXA-IXA and IXB-IXB, respectively. FIGS. 10A and 10B illustrate a step following the step shown in FIGS. 9A and 9B. FIGS. 11A and 11B illustrate a step following a step shown in FIGS. 10A and 10B. FIGS. 12A and 12B illustrate a step following the step shown in FIGS. 11A and 11B. FIGS. 13A and 13B illustrate a step following the step shown in FIGS. 12A and 12B. FIGS. 14A and 14B illustrate a step following the step shown in FIGS. 13A and 13B.

Referring to FIGS. 3A and 3B, an intrinsic a-Si layer 50 and an insulating layer 140 are sequentially deposited by chemical vapor deposition (CVD) on an insulating substrate 110 made of, for example, a material such as transparent glass or plastic. Then, a conductive layer 20 such as a metal, with a predetermined thickness, is deposited by performing, for example, a sputtering process, and a photoresist 30 with a thickness of about 1 to about 3 microns is coated on the conductive layer 20. A photomask 40 is arranged on the photoresist 30. The insulating layer 140 is made of, for example, silicon nitride, and has a thickness of about 2000 to about 5000 Å. The deposition temperature of the insulating layer 10 is, for example, in a range of about 250 to about 400° C.

The photo mask 40 includes a transparent substrate 41 and an opaque light blocking film 42 on the transparent substrate 41. The photo mask 40 is divided into light transmitting areas TA1, light blocking areas BA1, and translucent areas SA1. The light blocking film 42 has openings disposed in the light transmitting areas TA1 and slits disposed in the translucent areas SA1. The openings correspond to widths of the light transmitting and translucent areas TA1 and SA1. That is, the openings have widths that are approximately equal to widths the light transmitting areas TA1, and the slits have widths that are less than the widths of the translucent areas SA1.

After being developed by light through a photo mask 40, the photoresist 30 has a position-dependent thickness. The different thicknesses of the photoresist 30 enable selective etching of the underlying layers when using suitable process conditions. Therefore, a plurality of semiconductors 151 and 152 including source areas 154a and drain areas 154b, a plurality of metal patterns 71 for the data lines, and a plurality of gate lines 121 are obtained by a series of etching steps.

The formation of the semiconductors 151 and 152, the metal patterns 71 for the data lines, and the gate lines 121 will now be described in more detail.

Referring to FIGS. 3A and 3B, the translucent areas SA1 face the source areas 154a and the drain areas 154b of the semiconductors 151, the light blocking areas BA1 face the metal patterns 71 for the data lines and the gate lines 121, and the light transmitting areas TA1 face the remaining areas.

The photoresist 30 is exposed to light through the photo mask 40 and the photoresist 30 is developed such that portions of the photoresist 30 that have received a predetermined amount of light are removed. Referring to FIGS. 4A and 4B, portions of the photoresist 30 facing the light transmitting areas TA1 are removed, portions 34 of the photoresist 30 facing the translucent areas SA1 come to have a reduced thickness, and portions 32 of the photoresist 30 facing the light blocking areas BA1 remain.

Referring to FIGS. 5A and 5B, the exposed conductive layer 20, the insulating layer 140, and the intrinsic a-Si layer 50 are simultaneously etched using the remaining portions 32 and 34 of the photoresist 30 as an etch mask.

Referring to FIGS. 6A and 6B, the remaining portions 34 of the photoresist 30 are removed and the remaining portions 32 have reduced thicknesses. Thereby, the etched conductive layer 21 that is disposed under the portions 34 of the photoresist 30 becomes exposed.

Next, referring to FIGS. 7A and 7B, the exposed conductive layer 21 is etched using the remaining portions 32 of the photoresist 30 as an etch mask, to form a plurality of metal patterns 71 for the data lines and a plurality of gate lines 121.

Referring to FIGS. 8 to 9B, after removing the remaining portions 32 of the photoresist 30, semiconductors 151 and 152, including source areas 154a and drain areas 154b, are formed by doping an n-type impurity such as, for example, phosphorous, using an ion implanting process.

Referring to FIGS. 10A and 10B, a passivation layer 180 is formed on the metal patterns 71 for the data lines, the gate lines 121, and the exposed portions of the substrate 110 and the insulating layer 140, and a photoresist 50 is coated on the passivation layer 180. A photo mask 60 is arranged on the photoresist 50.

The photo mask 60 includes a transparent substrate 61 and an opaque light blocking film 62 on the transparent substrate 61. The photo mask 60 is divided into light transmitting areas TA2, light blocking areas BA2, and translucent areas SA2. The translucent areas SA2 approximately face the projections 127 of the gate lines 121 and areas between two metal patterns 71 for the data lines adjacent substantially in a longitudinal direction. The light transmitting areas TA2 face areas approximately enclosed by the metal patterns 71 for the data lines and the gate lines. The light blocking areas BA2 face the remaining areas.

The photoresist 50 is exposed to light through the photo mask 60, and the photoresist 50 is developed such that portions of the photoresist 50 that have received a predetermined amount of light are removed. Referring to FIGS. 11A and 11B, portions of the photoresist 50 facing the light transmitting areas TA2 are removed, portions 54 of the photoresist 50 facing the translucent areas SA2 come to have a reduced thickness, and portions 52 of the photoresist 50 facing the light blocking areas BA2 remain.

Referring to FIGS. 12A and 12B, the passivation layer 180 is etched using the remaining portions 52 and 54 of the photoresist 50 as an etch mask, to form a plurality of openings 186 exposing the metal patterns 71 for the data lines, a plurality of openings 187 exposing areas approximately enclosed by the metal patterns 71 for the data lines and the gate lines 121, and a plurality of contact holes 181 exposing the end portions 129 of the gate lines 121.

Next, referring to FIGS. 13A and 13B, the remaining portions 54 of the photoresist 50 are removed, and the remaining portions 52 have reduced thicknesses.

As shown in FIGS. 14A and 14B, a conductive film 90 made of, for example, IZO, ITO, or amorphous ITO is deposited on the metal patterns 71 for the data lines and the gate lines 121, the passivation layer 180, and the exposed substrate 110 by performing, for example, a sputtering process. When the conductive film 90 is made of, for example, IZO, IDIXO (indium x-metal oxide manufactured by, for example, Idemitsu Co. of Japan) may be used as a target material. The IZO may include, for example, In₂O₃ and ZnO, and the amount of Zn in the total amount of In and Zn may be, for example, about 15 to about 20 atomic %. The temperature of the sputtering is, for example, about 250° C. or less, to minimize contact resistance with other conductive layers.

The conductive film 90 includes fist portions 91 disposed on the portions 52 of the photoresist 50 and second portions 92 disposed on the remaining portions. Since the height difference between the top surface and the bottom of the photoresist 52 is relatively large due to the thickness of the photoresist 52, the first portions 91 and the second portions 92 of the conductive film 90 are separated from each other at least in part to form gaps therebetween, and lateral sides of the photoresist 52 are exposed at least in part.

The substrate 110 is then dipped into a developer such that the developer infiltrates into the photoresist 52 through the exposed lateral sides of the photoresist 52 to remove the photoresist 52. At this time, the first portions 91 of the conductive film 90 disposed on the photoresist 52 are removed along with the photoresist 52, which is referred to as “lift-off.” As a result, only the second portions 92 of the conductive film 90 are left to form a plurality of pixel electrodes 190, a plurality of data lines 171, and a plurality of contact assistants 81 as shown in FIGS. 1, 2A, and 2B.

The gate lines 121 and the semiconductors 151 and 152 including the source areas 154a and the drain areas 154b are formed by one photolithography process, and the pixel electrodes 191, the data lines 171, and the contact assistants 81 are also formed by one photolithography process. Thereby, an additional photolithography process for forming the gate lines 121 and an additional photolithography process for forming the pixel electrodes 191 and the contact assistants 81 are omitted such that the manufacturing process is simplified.

As a result, the time and cost for manufacturing a TFT array panel is decreased.

Although the exemplary embodiments have been described herein with reference to the accompanying drawings, the present invention is not limited to these embodiments, but may be modified in various forms without departing from the spirit or scope of the invention. All such changes and modifications are intended to be included within the scope of the invention as defined by the appended claims.

What is claimed is:

1. A method for manufacturing a thin film transistor (TFT) array panel, comprising:
forming an amorphous silicon layer, an insulating layer, and a conductive layer on a substrate;
forming a first photoresist on the conductive layer, wherein the first photoresist has a first portion and a second portion with a thickness less than the first portion;
simultaneously etching the conductive layer, the insulating layer, and the amorphous silicon layer using the first photoresist as a mask;
removing the second portion of the first photoresist;
removing an exposed portion of the conductive layer using the first portion of the first photoresist as a mask to form a gate line and a metal pattern for a data line;
removing the remaining portions of the first photoresist and doping an impurity to form a semiconductor having a source area and a drain area;
forming a passivation layer on the gate line, the metal pattern for a data line, an exposed portion of the insulating layer, and an exposed portion of the substrate;
forming a second photoresist on the passivation layer, wherein the second photoresist has a first portion and a second portion with a thickness less than the first portion;
etching the passivation layer using the second photoresist as a mask to expose a portion of the metal pattern for a data line and a portion of an area enclosed by the gate line and the metal pattern;
removing the second portion of the second photoresist;
depositing a conductive film; and
removing a remaining portion of the second photoresist to form a data line and a pixel electrode.

2. The method of claim 1, wherein the conductive film comprises a first portion disposed on the second photoresist and a second portion, and when the second photoresist is removed, a majority of the first portion of the conductive film is simultaneously removed.

3. The method of claim 1, wherein the first photoresist and the second photoresist are formed using a photomask having a light blocking area, a translucent area, and a light transmitting area.

4. The method of claim 1, wherein the first portion of the first photoresist and the first portion of the second photoresist have reduced thicknesses after the second portion of the first photoresist and the second portion of the second photoresist are removed.

5. The method of claim 4, wherein the removal of the second portion of the first photoresist and the second portion of the second photoresist comprises an ashing process.

6. The method of claim 1, wherein:
the etching of the passivation layer comprises exposing a portion of the gate line, and
the formation of the data line and the pixel electrode comprises forming a contact assistant on an exposed portion of the gate line.

7. A thin film transistor array panel comprising:
a semiconductor formed on a substrate, the semiconductor having a source area and a drain area;
an insulating layer formed on the semiconductor;
a gate line and a metal pattern for a data line formed on the insulating layer;
a passivation layer formed on the gate line and the metal pattern for a data line, wherein the passivation layer comprises a first opening exposing the metal pattern for a data line and a second opening exposing an area enclosed by the gate line and the metal pattern for a data line;
a data line formed on an exposed portion of the metal pattern for a data line, wherein the data line is connected to the source area; and
a pixel electrode formed on an exposed portion of the area enclosed by the gate line and the metal pattern for a data line, wherein the pixel electrode is connected to the drain area.

8. The thin film transistor array panel of claim 7, wherein the passivation layer is formed in an area between the pixel electrode overlapping the gate line.

9. The thin film transistor array panel of claim 7, wherein the passivation layer further comprises a contact hole exposing a portion of the gate line.

10. The thin film transistor array panel of claim 9, further comprising a contact assistant formed on an exposed portion of the gate line.

11. The thin film transistor array panel of claim 10, wherein the contact assistant has a boundary that is substantially the same as a boundary of the contact hole.

12. The thin film transistor array panel of claim 7, wherein the data line has a boundary that is substantially the same as the boundary of the first opening.

13. The thin film transistor array panel of claim 7, wherein the pixel electrode has a boundary that is substantially the same as the boundary of the second opening.

14. The thin film transistor array panel of claim 7, further comprising a storage electrode overlapping a portion of the pixel electrode.

15. The thin film transistor array panel of claim 14, wherein the storage electrode is connected to the gate line.

16. The thin film transistor array panel of claim 7, wherein the semiconductor has substantially the same planar shape as the insulating layer, the metal pattern for a data line, and the gate line except for the source area and the drain area.

17. A thin film transistor array panel comprising:
a semiconductor formed on a substrate, the semiconductor having a source area and a drain area;
an insulating layer formed on the semiconductor;
a gate line and a metal pattern for a data line formed on the insulating layer;
a passivation layer formed on the gate line and the metal pattern for a data line; and
a pixel electrode connected to the drain area.

18. The thin film transistor array panel of claim 17, wherein the passivation layer has a first opening exposing the metal pattern for a data line and a second opening exposing an area enclosed by the gate line.
